(19) United States
(12) Patent Application Publication
(10) Pub. No.: US 2008/0303075 A1
(43) Pub. Date: Dec. 11, 2008

(54) METHOD FOR FORMING ELEMENT ISOLATION STRUCTURE OF SEMICONDUCTOR DEVICE, ELEMENT ISOLATION STRUCTURE OF SEMICONDUCTOR DEVICE, AND SEMICONDUCTOR MEMORY DEVICE

(75) Inventor: Tsuyoshi SETOKUBO, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/135,383

(22) Filed: Jun. 9, 2008

(30) Foreign Application Priority Data
Jun. 11, 2007 (JP) 2007-154421

(51) Int. Cl. H01L 27/108; H01L 23/58; H01L 21/762

(52) U.S. Cl. 257/296; 438/435; 257/513; 257/E27.084; 257/E23.002; 257/E21.545

(57) ABSTRACT

A method for forming an element isolation structure of a semiconductor device, includes: a trench forming step of forming a trench on a semiconductor substrate; and a laminating step of forming alternately multilayered film in the trench by sequentially and alternately laminating a plurality of first insulating films that apply tensile stress to the semiconductor substrate and a plurality of second insulating films that apply compression stress to the semiconductor substrate so that the trench is filled with the alternately multilayered film.

### BACKGROUND OF THE INVENTION

1. Field of the Invention

The present invention relates to a method for forming an element isolation structure of a semiconductor device, an element isolation structure of a semiconductor device, and a semiconductor memory device. The present invention relates in particular to a method for forming an element isolation structure of a semiconductor device, an element isolation structure of a semiconductor device, and a semiconductor memory device, in which stress in an element isolation region of a semiconductor device can be reduced.

Priority is claimed on Japanese Patent Application No. 2007-154421, filed Jun. 11, 2007, the content of which is incorporated herein by reference.

2. Description of Related Art

As a measure for isolating a region on a semiconductor substrate in which semiconductor elements are to be formed, there is widely known a so-called STI (shallow trench isolation) structure in which a trench is formed on a semiconductor substrate and an insulating film is embedded therein.

As a method for forming a STI structure, Japanese Unexamined Patent Application, First Publication No. 2006-121021 discloses the following method. For example, a silicon nitride film is formed in a predetermined pattern on a semiconductor substrate such as a silicon wafer. Using this silicon nitride film as a mask, the semiconductor substrate is etched to form a trench. The semiconductor substrate is then subjected to thermal oxidization processing to form an oxidized film on the inner face of the trench An insulating film composed of silicon oxide is then laminated, for example, by means of a CVD (chemical vapor deposition) method so as to fill inside the trench. The insulating film is subjected to a CMP (chemical mechanical polishing) process to flatten the insulating film until the top face of the semiconductor substrate has been exposed. Thus, a STI structure is formed in which the trench is filled with the remaining section of the insulating film.

In the conventional STI structure, a silicon oxide film that serves as an insulating film is filled in the trench provided on a silicon wafer. The difference in materials of this silicon and silicon oxide causes a stress to occur between the trench and the silicon oxide film. This stress causes a stress to be applied to the silicon wafer, and results in crystal defects to occur in the silicon wafer, triggering leakage current. As a result, there has been a problem in the degraded data retention characteristic of DRAM (dynamic random access memory) elements formed on a semiconductor substrate.

### SUMMARY OF THE INVENTION

The present invention takes the above circumstances into consideration. An object of the present invention is to provide a method for forming an element isolation structure of a semiconductor device, and an element isolation structure of a semiconductor device, capable of preventing stress occurrence in a STI structure. Furthermore, an object of the present invention is to provide a semiconductor memory device capable of preventing stress occurrence in the STI structure to suppress leakage current, and of improving the data retention characteristic.

In order to achieve the above objects, a method for forming an element isolation structure of a semiconductor device, comprises: a trench forming step of forming a trench on a semiconductor substrate; and a laminating step of forming alternately multilayered film in the trench by sequentially and alternately laminating a plurality of first insulating films that apply tensile stress to the semiconductor substrate and a plurality of second insulating films that apply compression stress to the semiconductor substrate so that the trench is filled with the alternately multilayered film.

According to this forming method, the plurality of the first insulating films that apply tensile stress to the semiconductor substrate and the plurality of the second insulating films that apply compression stress to the semiconductor substrate are sequentially and alternately laminated so as to form an alternately multilayered insulative film. The trench is filled with this alternately multilayered film. Consequently, the stress between the trench and the alternately multilayered film can be alleviated. As a result, the stress applied to a silicon wafer is reduced and occurrence of crystal defects is suppressed, thereby enabling suppression of leakage current.

In the method for forming the element isolation structure of the semiconductor device of the present invention, the trench forming step may include a thermal oxidization process so as to form a thermally oxidized film on an inner face of the trench after the trench is formed, and the laminating step may include forming the alternately multilayered film so as to cover the thermally oxidized film.

According to this forming method, the thermally oxidized film is formed on the inner face of the trench, and therefore the corner sections on the inner face of the trench can be formed in smoothly curved faces. Consequently, it is possible to alleviate the stress between the trench and the alternately multilayered film that is reasonably likely to concentrate at the corner sections, and therefore leakage current can be further suppressed.

In the method for forming the element isolation structure of the semiconductor device of the present invention, in the laminating step, a film thickness ratio between the plurality of first insulating films and the plurality of second insulating films may be set so that a stress of the alternately multilayered film applied to the trench is alleviated.

According to this forming method, by adjusting the film thickness ratio between the first insulating film and the second insulating film, a stress of the alternately multilayered film applied to the trench is alleviated. Consequently, the alternately multilayered film can be easily optimized according to the dimensions and shape of the trench. As a result, leakage current can be reliably suppressed.

In the method for forming the element isolation structure of the semiconductor device of the present invention, the first insulating film may be a silicon nitride film and the second insulating film may be a silicon oxide film.

In the method for forming the element isolation structure of the semiconductor device of the present invention, a film thickness ratio between the first insulating film and the second insulating film may be within a range of 1:2.5 to 1:7.5.

In the method for forming the element isolation structure of the semiconductor device of the present invention, the first insulating film and the second insulating film may be laminated by means of an atomic layer deposition method.

According to this forming method, since the atomic layer deposition method is used in formation of the alternately multilayered film, a uniform film thickness of the first insulating film and the second insulating film to be formed inside the trench can be achieved. Consequently, the stress between the trench and the alternately multilayered film can be easily adjusted. Furthermore, use of the atomic layer deposition method enables formation of an insulating film with a film thickness of a few nanometers, and excellent step coverage. Consequently, it is possible to uniformly form the alternately multilayered film even in a relatively narrow trench.

The element isolation structure of the semiconductor device of the present invention comprises: a trench provided on a semiconductor substrate; and an insulative alternately multilayered film that fills within the trench, the alternately multilayered film being formed by sequentially and alternately laminating a plurality of first insulating films that apply tensile stress to the semiconductor substrate, and a plurality of second insulating films that apply compression stress to the semiconductor substrate.

According to this element isolation structure, the construction is such that the plurality of first insulating films that apply tensile stress to the semiconductor substrate and the plurality of second insulating films that apply compression stress to the semiconductor substrate are sequentially and alternately laminated so as to form the insulative alternately multilayered film, and the trench is filled with this alternately multilayered film. Consequently, the stress between the trench and the alternately multilayered film can be alleviated. Therefore, the stress applied to the silicon wafer is suppressed, and thereby occurrence of crystal defects is prevented. As a result, it is possible to suppress leakage current.

In the element isolation structure of the semiconductor device of the present invention, a thermally oxidized film may be formed on an inner face of the trench, and the alternately multilayered film is formed so as to cover the thermally oxidized film.

According to this element isolation structure, since the thermally oxidized film is formed on the inner face of the trench, the corner sections on the inner face of the trench are formed in smoothly curved faces. Consequently, it is possible to further alleviate the tensile stress or compression stress between the trench and the alternately multilayered film that is reasonably likely to concentrate at the corner sections. As a result, leakage current can be further suppressed.

In the element isolation structure of the semiconductor device of the present invention, a film thickness ratio between the plurality of first insulating films and the plurality of second insulating films may be set so that a stress of the alternately multilayered film applied to the trench is alleviated.

According to this element isolation structure, by adjusting the film thickness ratio between the first insulating film and the second insulating film, the stress of the alternately multilayered film applied to the trench is alleviated. Consequently, the alternately multilayered film can be easily optimized according to the dimensions and shape of the trench. As a result, leakage current can be reliably suppressed.

In the element isolation structure of the semiconductor device of the present invention, the first insulating film may be a silicon nitride film and the second insulating film may be a silicon oxide film.

In the element isolation structure of the semiconductor device of the present invention, a film thickness ratio between the first insulating film and the second insulating film may be within a range of 1:2.5 to 1:7.5.

In the element isolation structure of the semiconductor device of the present invention, the first insulating film and the second insulating film may be laminated by means of an atomic layer deposition method.

According to this element isolation structure, since the alternately multilayered film is formed by means of the atomic layer deposition method, a uniform film thickness of the first insulating film and the second insulating film to be formed in the trench can be achieved. Consequently, the stress between the trench and the alternately multilayered film can be easily adjusted. Furthermore, use of the atomic layer deposition method for forming the alternately multilayered film enables formation of an insulating film with a film thickness of a few nanometers, and excellent step coverage. Consequently, it is possible to uniformly form the alternately multilayered film even in a relatively narrow trench.

The semiconductor memory device of the present invention comprises: a semiconductor substrate having the element isolation structure of the semiconductor device of the present invention; a MOS transistor formed on the semiconductor substrate; and a capacitor connected to the MOS transistor.

According to this semiconductor memory device, since the semiconductor substrate has the above element isolation structure, it is possible to suppress occurrence of crystal defects in the semiconductor substrate, thereby suppressing leakage current. By suppressing leakage current, a reduction in the hold time in the semiconductor memory device can be prevented, and the frequency of refresh operations can be reduced.

According to the present invention, stress occurrence in the STI structure can be prevented. Furthermore, according to the semiconductor memory device pertain to an embodiment of the present invention, stress occurrence in the STI structure is prevented to suppress leakage current, thereby improving data retention characteristic.

### BRIEF DESCRIPTION OF THE DRAWINGS

FIG. 1 is a sectional schematic view showing an element isolation structure of a semiconductor device according to an embodiment of the present invention.

FIG. 2 is a process diagram for explaining a method for forming the element isolation structure of the semiconductor device according to the embodiment of the present invention, and is a sectional schematic view showing a trench forming step.

FIG. 3 is a process diagram for explaining a method for forming the element isolation structure of the semiconductor device according to the embodiment of the present invention, and is a sectional schematic view showing a step of forming a thermally oxidized film on trenches.

FIG. 4 is a process diagram for explaining a method for forming the element isolation structure of the semiconductor device according to the embodiment of the present invention, and is a sectional schematic view showing a lamination step.

FIG. 5 is a process diagram for explaining a method for forming the element isolation structure of the semiconductor device according to the embodiment of the present invention, and is a sectional schematic view showing a removal step.

FIG. 6 is a sectional schematic view showing a structure of the semiconductor memory device according to an embodiment of the present invention.

### DETAILED DESCRIPTION OF THE INVENTION

Hereinafter, an embodiment of the present invention is described, with reference to the drawings. The following drawings show an embodiment of an element isolation structure, a forming method thereof, and a semiconductor memory device of the present embodiment. The size, thickness, and dimensions of each section shown in the drawings may differ from size, thickness, and dimensions of each section in an actual element isolation structure.

### [Element Isolation Structure]

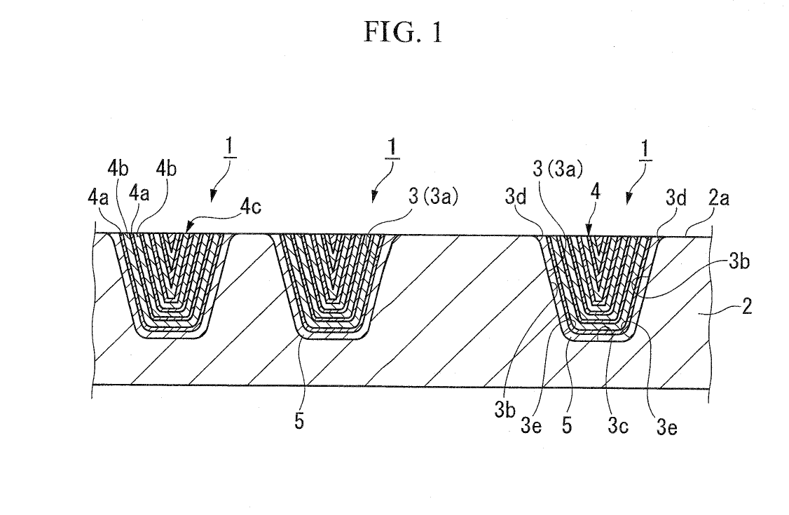

The element isolation structure of the semiconductor device according to the embodiment of the present invention is described, with reference to FIG. 1. As shown in FIG. 1, an element isolation structure 1 of the present embodiment generally includes a 25 semiconductor substrate 2 formed, for example, from a silicon wafer, trenches 3 provided in one face 2a of the semiconductor substrate 2, and alternately multilayered films 4 embedded in the trenches 3. On an inner face 3a of each of the trenches 3, there is formed a thermally oxidized film 5 composed of silicon oxide.

Each of the trenches 3 provided on the semiconductor substrate 2 is a trench having a substantially inverted trapezoidal sectional shape. For example, each of these trenches 3 is a trench such that the width of an opening thereof on the one face 2a is approximately 70 nm and the depth thereof is approximately 400 nm. Preferably these trenches 3 are formed for example by means of a photolithography technique. The sectional shape of the trench 3 is not limited to the inverted trapezoidal shape, as long as it is of a shape that can be applied in a conventional STI structure.

The inner face 3a of each trench 3 includes a pair of inclined faces 3b (inner face) and a bottom face 3c (inner face) between the pair of inclined faces 3b. On these inclined faces 3b and the bottom face 3c, there is formed the thermally oxidized film 5 composed of silicon oxide. The thickness of the thermally oxidized film 5 is, for example, approximately 13 nm. On each portion of the semiconductor substrate 2 that connects the one face 2a with the inclined face 3b there is formed a corner section 3d, and on each portion that connects the inclined face 3b and the bottom face 3c there is formed another corner section 3e. As a result of forming the thermally oxidized film 5, the shape of each of the corner sections 3d and 3e forms a smoothly curved face.

The alternately multilayered film 4 embedded in the trench 3 is configured such that a plurality of first insulating films 4a and a plurality of second insulating films 4b are alternately laminated. To give a detailed description, the order of the lamination is such that the first insulating film 4a is laminated on the thermally oxidized film 5 within the trench 3, the second insulating film 4b is laminated thereon, and the first insulating film 4a is further laminated thereon. As described above, the first insulating films 4a and the second insulating films 4b are sequentially and alternately laminated. The first insulating film 4a and the second insulating film 4b are formed by means of an atomic layer deposition method as described later, and therefore have an excellent step coverage and a uniform film thickness. Consequently, the initial first insulating film 4a is formed with a uniform film thickness along the inner face 3a of the trench 3. The second insulating film 4b to be laminated on this first insulating film 4a is formed with a uniform film thickness along the first insulating film 4a. Thereafter the first insulating films 4a and the second insulating films 4b are formed in a similar manner. A top face 4c of the alternately multilayered film 4 is substantially flush with the top face 2a of the semiconductor substrate 2.

Preferably the first insulating film 4a is a film that applies a tensile stress to the semiconductor substrate 2, and a silicon nitride film is preferable for example. Preferably the second insulating film 4b is a film that applies a compression stress to the semiconductor substrate 2, and a silicon oxide film is preferable for example. Here, a film that applies a tensile stress refers for example to a film that gives a stress that causes the semiconductor substrate to bend towards its film formation face side when the film is formed on the semiconductor substrate. A film that applies a compression stress refers for example to a film that gives a stress that causes the semiconductor substrate to bend towards the side opposite of the film formation face side when the film is formed on the semiconductor substrate. In the case where a silicon nitride film, as an example of the first insulating film 4a, is laminated with 1 nm film thickness on a silicon wafer, the tensile stress thereof is approximately 1,000 MPa. In the case where a silicon oxide film, as an example of the second insulating film 4b is laminated with 1 nm film thickness on a silicon wafer, the compression stress thereof is approximately 200 MPa.

When the first insulating films 4a that apply tensile stress and the second insulating films 4b that apply compression stress are alternately laminated, the tensile stress and the compression stress of the respective insulating films 4a and 4b are mutually alleviated.

Therefore, for example, the thermally oxidized film 5 formed on the inner face 3a of the trench 3 is a film composed of silicon oxide, and it gives a compression stress to the semiconductor substrate 2. Consequently, as a film to be laminated on this thermally oxidized film 5, the first insulating film 4a that gives a tensile stress is preferable, and specifically silicon nitride is suitable. That is to say, in the case where the thermally oxidized film 5 has been formed, it is preferable that the first insulating film 4a be laminated first when forming the alternately multilayered film 4. As a result, the stress applied to the semiconductor substrate 2 can be more effectively alleviated.

On the other hand, in the case where formation of the thermally oxidized film 5 is omitted and the alternately multilayered film 4 is formed directly on the semiconductor substrate 2, the order in initiating a lamination of the first insulating film 4a and the second insulating film 4b is not particularly limited, and either one may be laminated first.

The magnitude of the tensile stress of the first insulating film 4a and the magnitude of the compression stress of the second insulating film 4b can be respectively adjusted by controlling the film thickness of the respective insulating films 4a and 4b. For example, in the case where a silicon nitride film, as an example of the first insulating film 4a, is laminated with 1 nm film thickness on a silicon wafer, the tensile stress thereof is approximately 1,000 MPa as mentioned above. On the other hand, in the case where a silicon oxide film, as an example of the second insulating film 4b is laminated with 1 nm film thickness on a silicon wafer, the compression stress thereof is approximately 200 MPa. In this manner, the magnitude of stress that would be applied to a silicon wafer by a silicon oxide film is approximately one fifth of the stress that would be applied by a silicon nitride film with the same film thickness. Therefore, in the case of alternately laminating these silicon nitride films and silicon oxide films, if the film thickness of the silicon oxide film is increased to five times the film thickness of the silicon nitride film, then the internal tensile stress and the internal compression stress of the respective films become approximately equal to each other. As a result, the tensile stress and the compression stress can be mutually cancelled out.

The tensile stress of the first insulating film 4a and the compression stress of the second insulating film 4b are subject to the shape of the substrate that serves as a foundation of the films. That is to say, in the case of laminating the first and second insulating films 4a and 4b on the inner face 3a, the tensile stress and the compression stress may deviate from the above mentioned values in some cases. Therefore, in order to alleviate the stress applied to the semiconductor substrate 2 by forming the alternately multilayered film 4, it is preferable that the film thickness ratio of the first insulating film 4a and the second insulating film 4b ([first insulating film]:[second insulating film]) be adjusted within a range of 1:2.5 to 1:7.5, and for example, 1:5 is preferable. If the film thickness ratio falls outside this range, the alternately multilayered film 4 would give a large magnitude of stress to the semiconductor substrate 2, creating a possibility of leakage current, and hence this is undesirable.

The thicknesses of the respective first insulating film 4a and the second insulating film 4b are not particularly limited. However, for example, a preferable thickness of the first insulating film 4a is within a range of 1 nm to 3 nm, and a preferable thickness of the second insulating film 4b is within a range of 5 nm to 15 nm. If the total thickness of the films exceeds 20 mn, although it depends on the dimensions of the trench 3, the number of laminations of the respective insulating films 4a and 4b is significantly reduced, resulting in a difficulty in stress adjustment in some cases. If the total thickness of the films is less than 2 nm, the number of laminations of the respective insulating films 4a and 4b would increase significantly and the number of fabrication steps would increase as a result, and hence this is undesirable.

### [Method for Forming Element Isolation Structure]

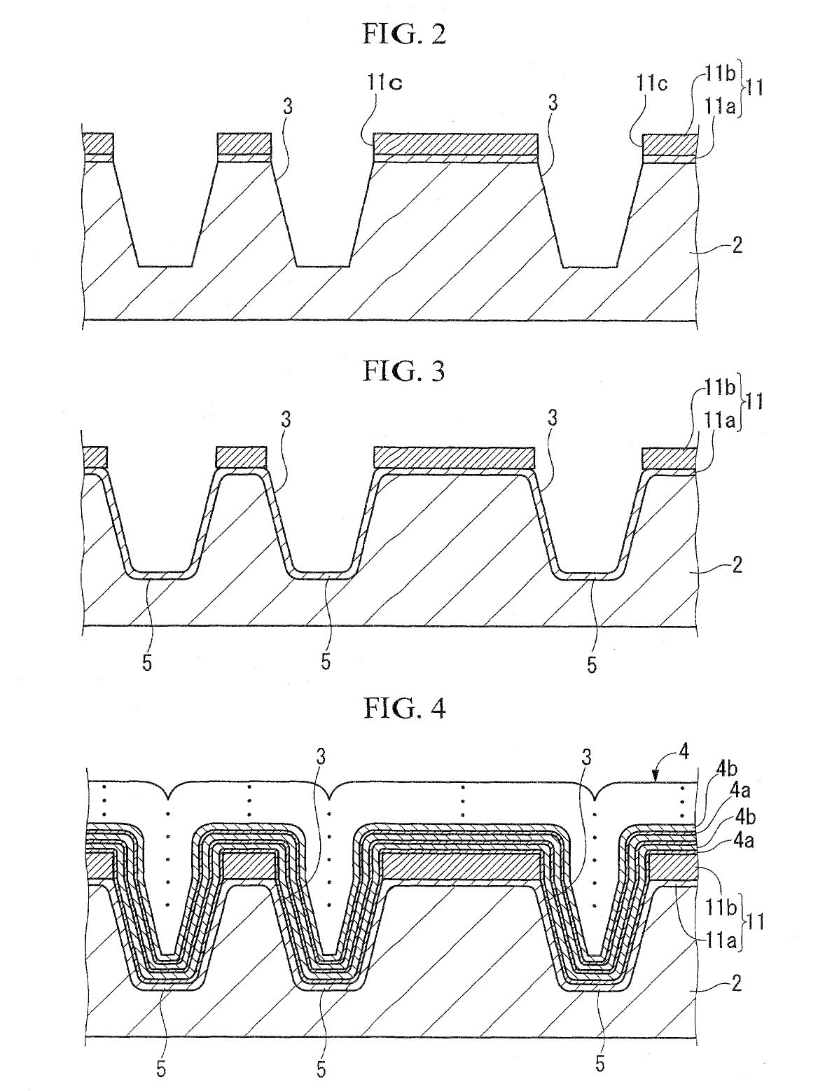

A method for forming an element isolation structure of a semiconductor device is described, with reference to FIG. 2 to FIG. 5. The method for forming an element isolation structure according to the present embodiment generally includes a trench forming step, a laminating step, and a removal step. Hereinafter, each of these steps is described in order.

### (Trench Forming Step)

In the trench forming step, a mask layer 11 is formed on the semiconductor substrate 2 composed of a silicon wafer, the mask layer 11 is partially removed, and an exposed predetermined region on the semiconductor substrate 2 is selectively etched, and thereby a trench is formed.

That is to say, as shown in FIG. 2, on the one face 2a of the semiconductor substrate 2, there are sequentially laminated a first mask layer 11a composed of silicon oxide for example and a second mask layer 11b composed of silicon nitride, thereby forming the mask layer 11. The mask layer 11 is etched so as to form an opening section 11c, thereby exposing a portion of the semiconductor substrate 2. This exposed portion on the semiconductor substrate 2 is then etched by means of a reactive ion etching method for example, so as to form the trenches 3.

Subsequently, the semiconductor substrate 2 having the trenches 3 formed thereon is subjected to a thermal oxidation process. As a result, as shown in FIG. 3, the thermally oxidized film 5 is formed on the inner face 3a of each trench 3. The thickness of the thermally oxidized film 5 may be adjusted by adjusting the conditions of the thermal oxidation process.

### (Laminating Step)

In the laminating step, a plurality of the first insulating films 4a and a plurality of the second insulating films 4b are sequentially and alternately laminated on the trench 3 and the mask layer 11 by means of an atomic layer deposition method so as to form the insulative alternately multilayered film 4, thereby providing this alternately multilayered film 4 in the trench 3 in an buried condition.

That is to say, as shown in FIG. 4, the first insulating film 4a is formed with a uniform thickness so as to cover the thermally oxidized film 5 of the trench 3 and the mask layer 11. Next, the second insulating film 4b is formed with a uniform thickness on the entire face of the first insulating film 4a. Subsequently, the first insulating film 4a is formed again with a uniform thickness on the entire face of the second insulating film 4b. Next, the second insulating film 4b is formed with a uniform thickness on the entire face of the first insulating film 4a. The alternately multilayered film 4 is formed by repeatedly performing the above sequence. The formation of the alternately multilayered film 4 is performed until at least the trench 3 has been completely filled with the alternately multilayered film 4.

It is preferable that the first insulating films 4a and the second insulating films 4b be formed by means of an atomic layer deposition method, because this method enables formation of an ultra thin film with a uniform thickness, providing excellent step coverage. The atomic layer deposition method is a method in which two or more types of material gases are supplied into a reaction chamber, and a film is formed by chemical reactions on the surface of a substrate installed within the reaction chamber. If the atomic layer deposition method is used, a thin film corresponding to one atomic layer level is formed at a high level of precision with each supply of the material gases. For example, in order to form a silicon nitride film that serves as the first insulating film 4a, a nitrogen-containing material gas and a silicon-containing material gas are alternately supplied onto the semiconductor substrate 2 so as to alternately laminate nitrogen atomic layers and silicon atomic layers. As a result, a silicon nitride film is formed. In order to form a silicon oxide film that serves as the second insulating film 4b, an oxygen-containing material gas and a silicon-containing material gas are alternately supplied onto the semiconductor substrate 2 so as to alternately laminate oxygen atomic layers and silicon atomic layers. As a result, a silicon oxide film is formed.

Preferred material gases to be used for forming a silicon nitride film include, for example, nitrogen-containing gases such as ammonia gas (NH₃) and nitrous oxide (N₂O), and silicon-containing gases such as mono-silane (SH₄) and dichlorosilane (SiH₂Cl₂). Preferred material gases to be used for forming a silicon oxide film include, for example, oxygen-containing gases such as oxygen gas (O₂) and nitrous oxide (N₂O), and silicon-containing gases such as mono-silane (SH₄) and dichlorosilane (SiH₂Cl₂)

Examples of other conditions of the atomic layer deposition method are described below. The internal temperature of the reaction chamber is made within a range of 500° C. to 600° C. Nitrogen (N₂) or the like is used as a carrier gas for the material gases. The back pressure within the reaction chamber is set within a range of 20 Pa to 30 Pa. The pressure within the reaction chamber when introducing the carrier gas containing a material gas, is set within a range of 300 Pa to 600 Pa. An amount of material gas supply is made within a range of 5 to 10 L. Switching between the material gases may be performed as described below. After completing supply of the first type of material gas, the reaction chamber is depressurized and exhausted. Subsequently, a carrier gas containing no material gases is introduced into the reaction chamber to purge inside the reaction chamber. Next, the second type of material gas is introduced together with the carrier gas.

A method for forming, for example, a silicon nitride film that serves as the first insulating film 4a is described below The semiconductor substrate 2 is positioned inside the reaction chamber, and the temperature, atmosphere, and pressure inside the reaction chamber are set to predetermined conditions. Next, a silicon-containing material gas together with the carrier gas is introduced into the reaction chamber, and a silicon atomic layer is formed on the entire face of the trench 3 of the semiconductor substrate 2 and the mask layer 11. Then, after performing a purging process, a nitrogen-containing material gas together with the carrier gas is introduced into the reaction chamber, and a nitrogen atomic layer is formed on the entire face of the silicon atomic layer. Thus, by alternately laminating silicon atomic layers and nitrogen atomic layers, the first insulating film 4a composed of a silicon nitride film is formed.

A method for forming, for example, a silicon oxide film that serves as the second insulating film 4b is described below. After forming the silicon atomic layer that constitutes the silicon nitride film, an oxygen-containing material gas is supplied in place of the nitrogen-containing material gas. An oxygen atomic layer is formed on the silicon atomic layer. Then, the silicon atomic layers and the oxygen atomic layers are alternately laminated. By performing the above step, the second insulating film 4b composed of a silicon oxide film is formed.

As described above, by appropriately changing the types of material gases, the first insulating films 4a (silicon nitride films) and the second insulating films 4b (silicon oxide films) can be continuously formed.

The film thicknesses of the first insulating film 4a (silicon nitride film) and the second insulating film 4b (silicon oxide film) can be adjusted by adjusting the number of laminations of the respective atomic layers. The film thickness ratio between the first insulating film 4a and the second insulating film 4b may be adjusted within the above mentioned range. By adjusting the film thickness ratio within an appropriate range, the stress between the trench 3 and the alternately multilayered film 4 can be alleviated.

In the present embodiment, the method for forming an alternately laminated film with use of the atomic layer deposition method has been described. However, the alternately laminated film may be formed by means of a conventional CVD method.

### (Removal Step)

In the removal step, the alternately multilayered film 4 on the mask layer 11 is removed, while the alternately multilayered film 4 remains within the trench 3.

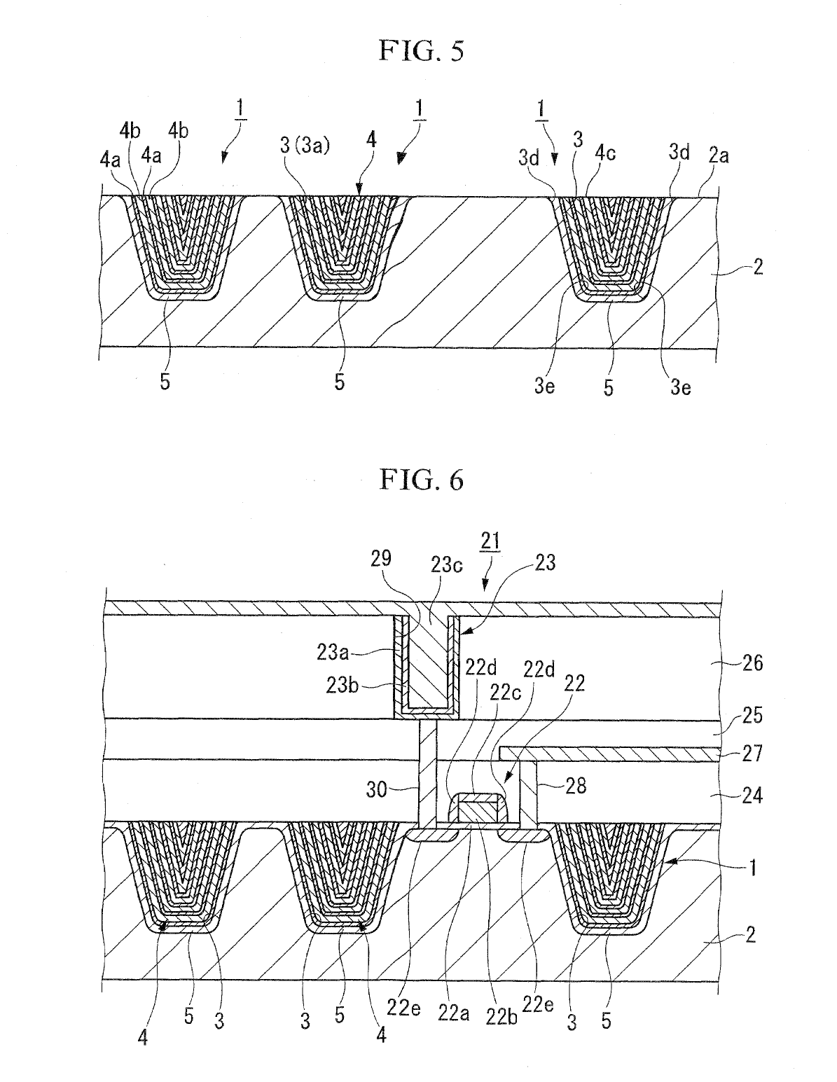

That is to say, as shown in FIG. 4 and FIG. 5, with the second mask layer 11b that constitutes the mask layer 11, serving as an etching stopper, the alternately multilayered film 4 is flattened by means of a CMP method for example. The CMP processing may be performed to the point where the one face 2a of the semiconductor substrate 2 has been exposed. As a result the alternately multilayered film 4 and the mask layer 11 on the one face 2a are removed, and only the alternately multilayered film 4 embedded within the trench 3 remains. By means of this CMP processing, the top face 4c which is flash with the one face 2a of the semiconductor substrate 2, is formed on the alternately multilayered film 4.

In this way, there is formed the element isolation structure 1 with the alternately multilayered film 4 embedded in the trench 3 of the semiconductor substrate 2.

### [Semiconductor Memory Device]

FIG. 6 is a sectional view schematically showing part of a semiconductor memory device according to the present embodiment. This semiconductor memory device 21 is formed on the semiconductor substrate 2 having the element isolation structure 1 of the present embodiment.

The semiconductor memory device 21 shown in FIG. 6 generally includes a MOS transistor 22 formed on the semiconductor substrate 2, and a capacitor 23 connected to the source/drain regions of the MOS transistor 22.

The MOS transistor 22 includes a gate insulating film 22a, a gate electrode 22b, a silicon nitride film 22c, side walls 22d, and the source/drain regions 22e. The gate insulating film 22a is formed on the semiconductor substrate 2. The gate electrode 22b is formed on the gate insulating film 22a. The silicon nitride film 22c is formed on the gate electrode 22b. The side walls 22d are composed of silicon nitride and are formed on side faces of the gate electrode 22b. The source/drain regions 22e are formed in the semiconductor substrate 2 on both sides of the gate electrode 22b.

On the semiconductor substrate 2, there are sequentially laminated a first interlayer insulating film 24, a second interlayer insulating film 25, and a third interlayer insulating film 26. On the first interlayer insulating film 24 there is formed a bit line 27. This bit line 27 is connected, via a bit line contact plug 28 passing through the first interlayer insulating film 24, to one of the source/drain regions 22e of the MOS transistor 22.

In the third interlayer insulating film 26 there is provided a through hole 29. On the inner face of this through hole 29 there are formed a lower electrode layer 23a and a dielectric layer 23b. In the through hole 29, there is formed an upper electrode layer 23c so as to cover the dielectric layer 23b. The lower electrode layer 23a, the dielectric layer 23b, and the upper electric layer 23c constitute the capacitor 23. On the lower side of the capacitor 23, there is formed a capacitance contact plug 30 that passes through the first and second interlayer insulating films 24 and 25. This capacitance contact plug 30 connects the capacitor 23 to another of the source/drain regions 22e of the MOS (metal oxide semiconductor) transistor 22.

Since the semiconductor memory device 21 shown in FIG. 6 is formed on the semiconductor substrate 2 having the element isolation structure 1, a reduction in hold time caused by leakage current is suppressed. As a result, the frequency of the refresh operation can be reduced.

As described above, the element isolation structure 1 is configured such that the insulative alternately multilayered film 4 is provided in which a plurality of the first insulating films 4a that apply tensile stress to the semiconductor substrate 2 and a plurality of the second insulating films 4b that apply compression stress to the semiconductor substrate 2 are sequentially and alternately laminated, and this alternately multilayered film 4 is embedded in the trench 3. Consequently, a stress between the trench 3 and the alternately multilayered film 4 can be alleviated. As a result, occurrence of crystal defects in the semiconductor substrate 2 is suppressed, and leakage current can be thereby suppressed.

Furthermore, the alternately multilayered film 4 is formed by means of an atomic layer deposition method. As a result, the film thicknesses of the first insulating film 4a and the second insulating film 4b to be formed within the trench 3 can be made uniform, and therefore the stress between the trench 3 and the alternately multilayered film 4 can be easily adjusted. Furthermore, as a result of forming the alternately multilayered film 4 by means of the atomic layer deposition method, it is possible to form the insulating films 4a and 4b with a film thickness of a few nanometers, and excellent step coverage. As a result, the alternately multilayered film 4 can be uniformly formed even in a relatively narrow trench 3.

Moreover, according to the above mentioned element isolation structure 1, since the thermally oxidized film 5 is formed on the inner face 3a of the trench 3, the corner sections 3d and 3e on the inner face 3a of the trench 3 are formed in smoothly curved faces. Consequently, it is possible to alleviate the stress between the trench 3 and the alternately multilayered film 4 that is reasonably likely to concentrate at the corner sections 3d and 3e, and therefore leakage current can be further suppressed.

Furthermore, according to the element isolation structure 1 of the above semiconductor device, by adjusting the film thickness ratio between the first insulating film 4a and the second insulating film 4b, the stress between the trench 3 and the alternately multilayered film 4 is alleviated. Consequently, the alternately multilayered film 4 can be easily optimized according to the dimensions and shape of the trench 3. As a result, leakage current can be reliably suppressed.

According to the above method for forming the element isolation structure 1, a plurality of the first insulating films 4a that apply tensile stress and a plurality of the second insulating films 4b that apply compression stress are sequentially and alternately laminated so as to form the insulative alternately multilayered film 4, and this alternately multilayered film 4 is embedded in the trench 3. Consequently, the stress between the trench 3 and the alternately multilayered film 4 can be alleviated. As a result, occurrence of crystal defects in the semiconductor substrate 2 can be suppressed, thereby suppressing leakage current.

Moreover, since the atomic layer deposition method is used when forming the alternately multilayered film 4, the film thicknesses of the first insulating film 4a and the second insulating film 4b to be formed in the trench 3 can be made uniform. Consequently, the stress between the trench 3 and the alternately multilayered film 4 can be easily adjusted. Furthermore, as a result of employing the atomic layer deposition method, it is possible to form the insulating films 4a and 4b with a film thickness of a few nanometers, and excellent step coverage. As a result, the alternately multilayered film 4 can be uniformly formed even in a relatively narrow trench 3.

Moreover, according to the above mentioned method for forming the element isolation structure 1, the thermally oxidized film 5 is formed on the inner face 3a of the trench 3. Consequently, it is possible to form the corner sections 3d and 3e on the inner face 3a of the trench 3 in smoothly curved faces. Thus, the stress between the trench 3 and the alternately multilayered film 4 that is reasonably likely to concentrate at the corner sections 3d and 3e can be further alleviated. As a result, leakage current can be further suppressed.

Furthermore, by adjusting the film thickness ratio between the first insulating film 4a and the second insulating film 4b, the stress between the trench 3 and the alternately multilayered film 4 is alleviated. Consequently, the alternately multilayered film 4 can be easily optimized according to the dimensions and shape of the trench 3. As a result, leakage current can be reliably suppressed.

Moreover, according to the above mentioned semiconductor memory device 21, on the semiconductor substrate 2 there is provided the element isolation structure 1. Consequently, it is possible to suppress occurrence of crystal defects in the semiconductor substrate 2 and to suppress leakage current. By suppressing leakage current, a reduction in the hold time in the semiconductor memory device 21 can be prevented, and the frequency of refresh operations can be reduced.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method for forming an element isolation structure of a semiconductor device, comprising:
a trench forming step of forming a trench on a semiconductor substrate; and
a laminating step of forming alternately multilayered film in the trench by sequentially and alternately laminating a plurality of first insulating films that apply tensile stress to the semiconductor substrate and a plurality of second insulating films that apply compression stress to the semiconductor substrate so that the trench is filled with the alternately multilayered film.

2. A method for forming an element isolation structure of a semiconductor device according to claim 1, wherein
in the trench forming step, a thermal oxidization process is performed so as to form a thermally oxidized film on an inner face of the trench after the trench is formed, and
in the laminating step, the alternately multilayered film is formed so as to cover the thermally oxidized film.

3. A method for forming an element isolation structure of a semiconductor device according to claim 1, wherein in the laminating step, a film thickness ratio between the plurality of first insulating films and the plurality of second insulating films is set so that a stress of the alternately multilayered film applied to the trench is alleviated.

4. A method for forming an element isolation structure of a semiconductor device according to claim 1, wherein the first insulating film is a silicon nitride film and the second insulating film is a silicon oxide film.

5. A method for forming an element isolation structure of a semiconductor device according to claim 1, wherein a film thickness ratio between the first insulating film and the second insulating film is within a range of 1:2.5 to 1:7.5.

6. A method for forming an element isolation structure of a semiconductor device according to claim 1, wherein the first insulating film and the second insulating film are laminated by means of an atomic layer deposition method.

7. An element isolation structure of a semiconductor device comprising:
a trench provided on a semiconductor substrate; and
an insulative alternately multilayered film that fills within the trench,
the alternately multilayered film being formed by sequentially and alternately laminating a plurality of first insulating films that apply tensile stress to the semiconductor substrate, and a plurality of second insulating films that apply compression stress to the semiconductor substrate.

8. An element isolation structure of a semiconductor device according to claim 7, wherein a thermally oxidized film is formed on an inner face of the trench, and the alternately multilayered film is formed so as to cover the thermally oxidized film.

9. An element isolation structure of a semiconductor device according to claim 7, wherein a film thickness ratio between the plurality of first insulating films and the plurality of second insulating films is set so that a stress of the alternately multilayered film applied to the trench is alleviated.

10. An element isolation structure of a semiconductor device according to claim 7, wherein the first insulating film is a silicon nitride film and the second insulating film is a silicon oxide film.

11. An element isolation structure of a semiconductor device according to claim 7, wherein a film thickness ratio between the first insulating film and the second insulating film is within a range of 1:2.5 to 1:7.5.

12. An element isolation structure of a semiconductor device according to claim 7, wherein the first insulating film and the second insulating film are laminated by means of an atomic layer deposition method.

13. A semiconductor memory device comprising:
a semiconductor substrate having an element isolation structure of a semiconductor device according to claim 7;
a MOS transistor formed on the semiconductor substrate; and
a capacitor connected to the MOS transistor.
